(19) United States
(12) Patent Application Publication
(10) Pub. No.: US 2009/0140351 A1
(43) Pub. Date: Jun. 4, 2009

(54) MOS Devices Having Elevated Source/Drain Regions

(76) Inventors: Hong-Nien Lin, Taichung (TW); Chih-Hsin Ko, Fongshan (TW); Hung-Wei Chen, Hsin-Chu (TW); Wen-Chin Lee, Hsin-Chu (TW)

Correspondence Address: SLATER & MATSIL, L.L.P., 17950 PRESTON ROAD, SUITE 1000, DALLAS, TX, 75252, US

(21) Appl. No.: 11/948,823

(22) Filed: Nov. 30, 2007

(51) Int. Cl. H01L 29/78

(52) U.S. Cl. 257/407; 257/408; 257/E29.271; 257/E29.266

(57) ABSTRACT

A method for forming a semiconductor device includes providing a semiconductor substrate; forming a gate dielectric over the semiconductor substrate; forming a gate electrode over the gate dielectric; forming a slim spacer on sidewalls of the gate dielectric and the gate electrode; forming a silicon carbon (SiC) region adjacent the slim spacer; forming a deep source/drain region comprising at least a portion of the silicon carbon region; blanket forming a metal layer, wherein a first interface between the metal layer and the deep source/drain is higher than a second interface between the gate dielectric and the semiconductor substrate; and annealing the semiconductor device to form a silicide region. Preferably, a horizontal spacing between an inner edge of the silicide region and a respective edge of the gate electrode is preferably less than about 150 Å.

### TECHNICAL FIELD

This invention relates generally to semiconductor devices, and more particularly to metal-oxide-semiconductor (MOS) devices with elevated source and drain regions.

### BACKGROUND

Reduction of the size and the inherent features of semiconductor devices (e.g., a metal-oxide-semiconductor device) has enabled continued improvements in speed, performance, density, and cost per unit function of integrated circuits over the past few decades.

To enhance the performance of MOS devices, stress may be introduced into the channel region of a MOS transistor to improve carrier mobility. Generally, it is desirable to induce a tensile stress in the channel region of an n-type metal-oxide-semiconductor (NMOS) device in a source-to-drain direction and to induce a compressive stress in the channel region of a p-type metal-oxide-semiconductor (PMOS) device in a source-to-drain direction.

Two methods are commonly used for applying tensile stresses to the channel regions of NMOS devices. One of the methods is to form SiC stressors by implanting carbon into source and drain regions. The other method is to epitaxially growing SiC stressors in the source and drain regions. Such a method typically includes the steps of forming a gate stack on a semiconductor substrate, forming gate spacers on sidewalls of the gate stack, forming recesses in the silicon substrate aligned with the gate spacers, and epitaxially grow SiC stressors in the recesses. SiC has a smaller lattice constant than silicon, and hence applies a tensile stress to the channel region, which is located between a source SiC stressor and a drain SiC stressor.

It has been found that both methods are not helpful for improving the source/drain resistances R_{SD}. The source/drain regions formed by epitaxially growing SiC have comparable resistances R_{SD} as the source/drain regions formed by implanting an n-type impurity into silicon substrate. The resistances R_{SD} of the source/drain regions formed by implanting carbon may even be lower than the resistances R_{SD} of the source/drain regions formed without implanting carbon.

It is well known that the source/drain resistances R_{SD} play an important role in the drive currents. With the scaling of integrated circuits, source/drain resistances R_{SD} become increasingly greater relative to the channel resistance R_{CH}. Since the device drive currents are inversely proportional to the total resistance (R_{SD}+R_{CH}), the increase in drive currents is at least partially offset by the increase in source/drain resistances R_{SD}. When technologies evolve to 65 nm and beyond, the benefit of stressing channels to increase device drive currents is so small that the benefit will no longer be worth the process complexity introduced for generating stresses, and it is expected that in 45 nm technology and below, source/drain resistances R_{SD} will far exceed channel resistance R_{CH}. Beyond 45 nm technology, source/drain resistances R_{SD} become the bottleneck for further improving device performance. A semiconductor device that may overcome the previously discussed deficiencies is thus needed.

### SUMMARY OF THE INVENTION

In accordance with one aspect of the present invention, a method for forming a semiconductor device includes providing a semiconductor substrate; forming a gate dielectric over the semiconductor substrate; forming a gate electrode over the gate dielectric; forming a slim spacer on sidewalls of the gate dielectric and the gate electrode; forming a silicon carbon (SiC) region adjacent the slim spacer; forming a deep source/drain region comprising at least a portion of the silicon carbon region; blanket forming a metal layer, wherein a first interface between the metal layer and the deep source/drain is higher than a second interface between the gate dielectric and the semiconductor substrate; and annealing the semiconductor device to form a silicide region.

In accordance with another aspect of the present invention, a method for forming a semiconductor device includes providing a semiconductor substrate; forming a gate dielectric over the semiconductor substrate; forming a gate electrode over the gate dielectric; forming a dummy slim spacer on sidewalls of the gate dielectric and the gate electrode; forming a recess in the semiconductor substrate and along a sidewall of the dummy slim spacer; epitaxially growing a silicon carbon (SiC) region in the recess, wherein the SiC region has a top surface no higher than an interface between the gate dielectric and the semiconductor substrate; selectively forming a silicon layer on the SiC region, wherein the silicon layer has a top surface higher than the interface; removing the dummy slim spacer; forming a lightly doped source/drain (LDD) region by implanting the silicon layer; forming a slim spacer on sidewalls of the gate dielectric and the gate electrode; forming a dummy spacer on a sidewall of the slim spacer; forming a deep source/drain region including at least a portion of the silicon carbon region; removing the dummy spacer; and forming a silicide region over the SiC region.

In accordance with yet another aspect of the present invention, a method for forming a semiconductor device includes providing a semiconductor substrate; forming a gate dielectric over the semiconductor substrate; forming a gate electrode over the gate dielectric; forming a dummy slim spacer on sidewalls of the gate dielectric and the gate electrode; forming a recess in the semiconductor substrate and along a sidewall of the dummy slim spacer; epitaxially growing a silicon carbon (SiC) region in the recess, wherein the SiC region has a top surface higher than an interface between the gate dielectric and the semiconductor substrate; removing the dummy slim spacer; forming a lightly doped source/drain (LDD) region by implanting the SiC region; forming a slim spacer on sidewalls of the gate dielectric and the gate electrode; forming a dummy spacer on a sidewall of the slim spacer; forming a deep source/drain region including at least a portion of the SiC region; removing the dummy spacer; and forming a silicide region on the SiC region.

In accordance with yet another aspect of the present invention, a semiconductor device includes a semiconductor substrate; a gate dielectric over the semiconductor substrate; a gate electrode over the gate dielectric; a SiC region adjacent the gate dielectric and having at least a portion in the semiconductor substrate; a deep source/drain region comprising at least a portion of the SiC region; and a silicide region over the deep source/drain region, wherein an inner edge of the silicide region is closer to the gate electrode than the deep source/drain region. A horizontal spacing between an inner edge of the silicide region and a respective edge of the gate electrode is preferably less than about 150 Å.

In accordance with yet another aspect of the present invention, a semiconductor structure includes a semiconductor substrate; a gate dielectric over the semiconductor substrate; a gate electrode over the gate dielectric; a slim spacer on a sidewall of the gate electrode; a SiC stressor in the semiconductor substrate and adjacent the gate electrode; and a silicide region having an inner edge substantially aligned to an outer edge of the slim spacer, wherein the silicide has a bottom surface substantially higher than a top surface of the semiconductor substrate. A horizontal spacing between an inner edge of the silicide region and a respective edge of the gate electrode is preferably less than about 150 Å.

The advantageous features of the present invention include increased drive currents and reduced leakages currents of MOS devices.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 9A are cross-sectional views of intermediate stages in the manufacturing of an n-type metal-oxide-semiconductor (MOS); and

FIGS. 9B through 9D illustrate alternative embodiments of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for improving drive currents of metal-oxide-semiconductor devices without causing an increase in leakage currents is provided. The intermediate stages of manufacturing embodiments of the present invention are illustrated. Throughout the various views and illustrative embodiments of the present invention, like reference numbers are used to designate like elements.

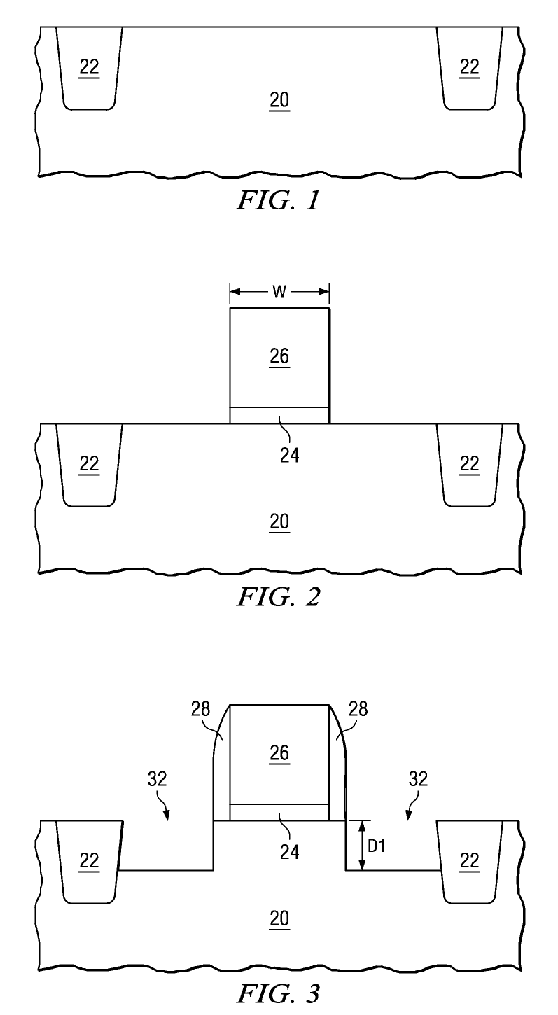

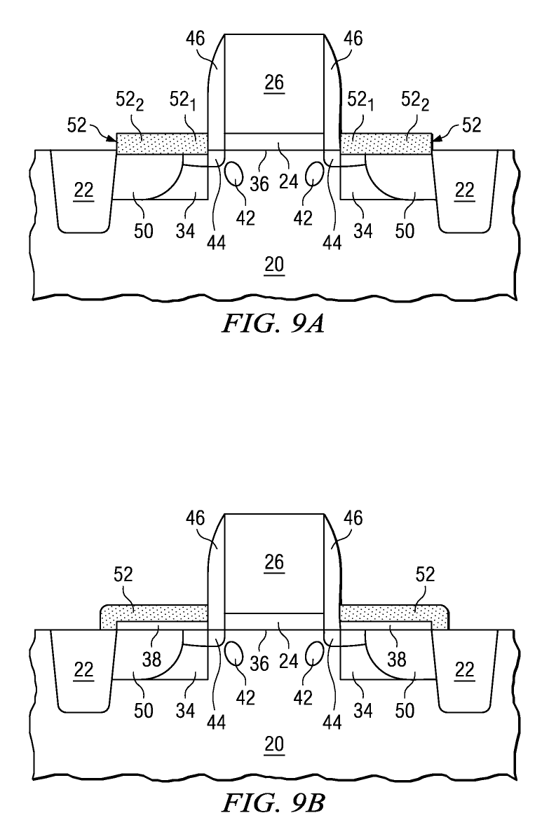

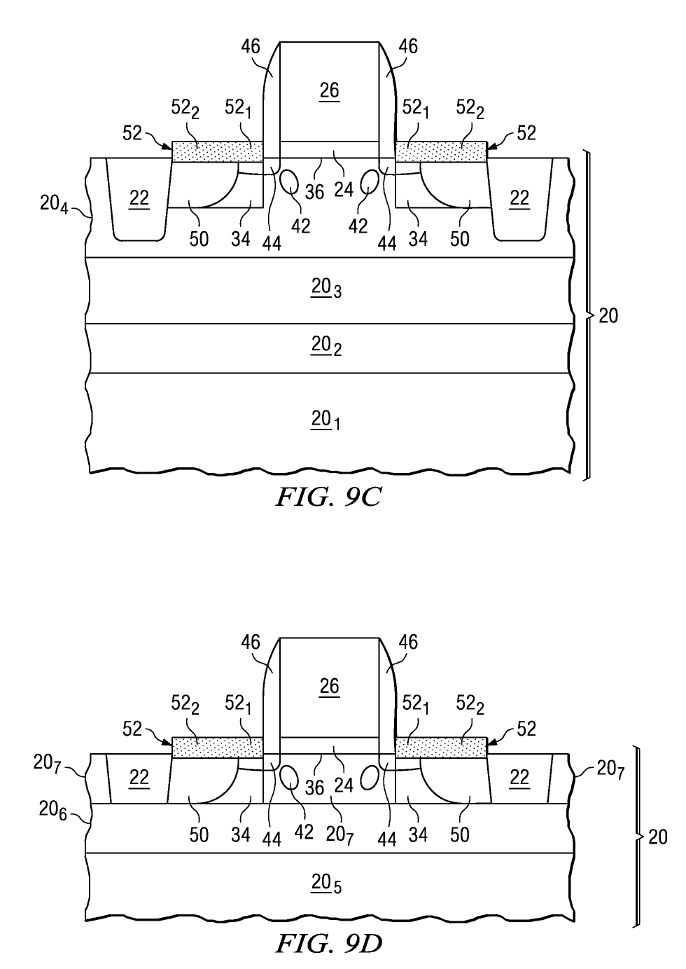

Referring to FIG. 1, substrate 20 is provided. In an embodiment, substrate 20 is formed of bulk silicon. In alternative embodiments, substrate 20 has a silicon-on-insulator (SOI) structure (please refer to FIG. 9D). In yet other embodiments, substrate 20 includes strained silicon, which may be formed on a silicon germanium layer, either relaxed or strained (please refer to FIG. 9C). In yet other embodiments, substrate 20 has a strained silicon-on-insulator (SSOI) structure.

Shallow trench isolation (STI) regions 22 are formed in substrate 20 to isolate device regions. As is known in the art, STI regions 22 may be formed by etching substrate 20 to form recesses, and then filling the recesses with dielectric materials.

FIG. 2 illustrates a gate stack, including gate dielectric 24 and gate electrode 26, on substrate 20. Gate dielectric 24 preferably includes commonly used dielectric materials such as oxides, nitrides, oxynitrides, high-k materials, combinations thereof, and multi-layers thereof. Gate electrode 26 may be formed of polysilicon, and impurities may be doped to improve its conductivity as the deposition proceeds. Alternatively, gate electrode 26 is formed of other commonly used conductive materials such as metals, metal silicides, metal nitrides, and combinations thereof. The width W of gate electrode 26 is preferably less than about 100 nm, and more preferably less than about 50 nm. As is known in the art, gate dielectric 24 and gate electrode 26 may be formed by stacking a gate electrode layer on a gate dielectric layer, and then patterning the stacked layers.

FIG. 3 illustrates the formation of dummy slim (gate) spacers 28. Throughout the description, the term “slim spacer” refers to the spaces having thicknesses of less than about 150 Å. More preferably, slim spacers have a thickness of between about 20 Å and about 100 Å. Dummy slim spacers 28 may be formed of a single layer including commonly used spacer materials, such as silicon nitride, silicon oxynitride, silicon oxide, tetra-ethyl-ortho-silicate (TEOS) oxide, and combinations thereof. Alternatively, dummy slim spacers 28 are each a composite layer including more than one layer, for example, a silicon nitride of about 50 Å on a TEOS oxide of about 20 Å. As is known in the art, the formation of dummy slim spacers 28 may include forming a spacer layer(s), and then patterning the spacer layer(s) to remove its horizontal portions. The deposition may be performed using commonly used techniques, such as plasma enhanced chemical vapor deposition (PECVD), low-pressure chemical vapor deposition (LPCVD), sub-atmospheric chemical vapor deposition (SACVD), and the like.

Next, as also shown in FIG. 3, recesses 32 are formed in substrate 30. Preferably, recesses 32 are formed substantially along the edges of slim spacers 28, by etching isotropically or anisotropically. The depth D1 of recesses 32 may be between about 200 Å and about 1000 Å, although depth D1 may be greater or smaller. In the case substrate 20 has a SOI structure as shown in FIG. 9D, a thin seed silicon layer needs to be left at the bottoms of recesses 32 and on buried oxide layer 20₆.

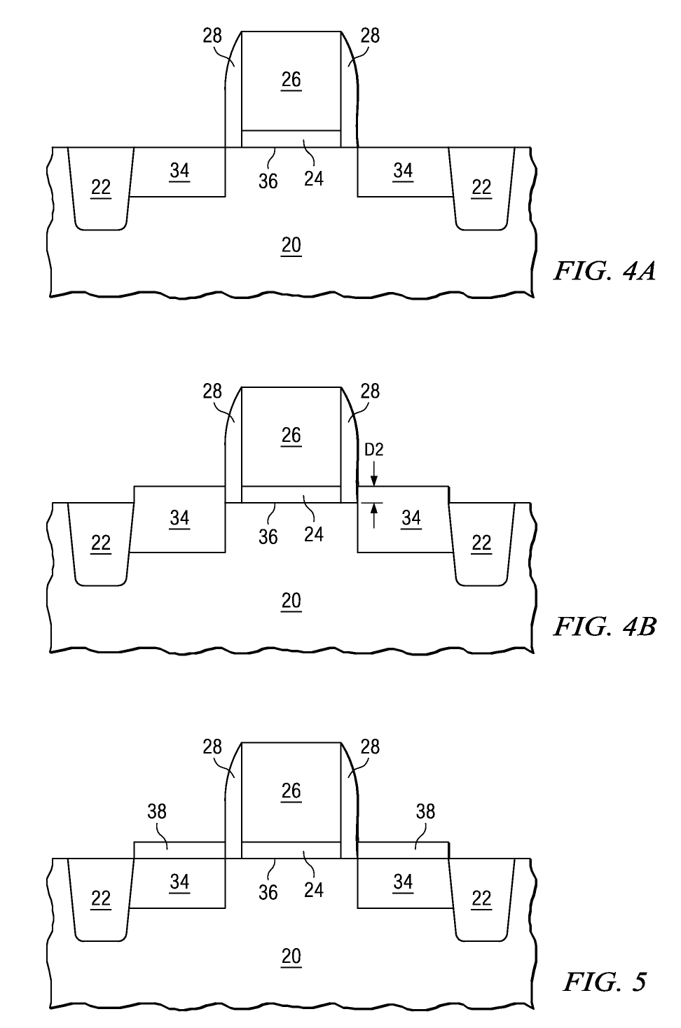

Recesses 32 are then filled to form silicon carbon (SiC) regions 34, as illustrated in FIG. 4A, preferably by selective epitaxially growth (SEG) of SiC in the recesses 32. An n-type impurity, such as arsenic, may be simultaneously doped with the proceeding of the SEG. Alternatively, no n-type impurity is doped during the SEG. In the preferred embodiment, the carbon atomic percentage in SiC regions 34 is greater than about 1 percent, and more preferably between about 1 percent and about 3 percent. In an embodiment, SiC regions 34 have a top surface substantially level with interface 36, which is between gate dielectric 24 and the underlying substrate 20. In other embodiments, as shown in FIG. 4B, the top surfaces of SiC regions 34 are higher than interface 36, for example, by a distance D2 of between about 50 Å and about 200 Å, and hence SiC regions 34 are referred to as raised regions. In yet other embodiments, the top surfaces of SiC regions 34 are lower than interface 36.

FIG. 5 illustrates the optional formation of silicon layers 38, for example, by SEG. Preferably, silicon layers 38 are formed if the top surfaces of SiC regions 34 are level with or lower than interface 36, and the top surfaces of the resulting silicon layers 38 are higher than interface 36. In an exemplary embodiment, the top surfaces of silicon layers 38 are higher than interface 36 by a vertical distance in a same range as distance D2 as shown in FIG. 4B, which is between about 50 Å and about 200 Å. Silicon layers 38 preferably include substantially pure silicon. Advantageously, silicon layers 38 on SiC regions 34 incur less process cost and complexity than epitaxially growing SiC regions 34 that have combined thickness of silicon layers 38 and SiC regions 34. This is due to the fact that it is more difficult to epitaxially growing SiC layers than silicon layers, especially if the SiC layers have high carbon concentrations. In addition, in the subsequently performed silicidation process, silicide formation on a silicon layer is a mature technique.

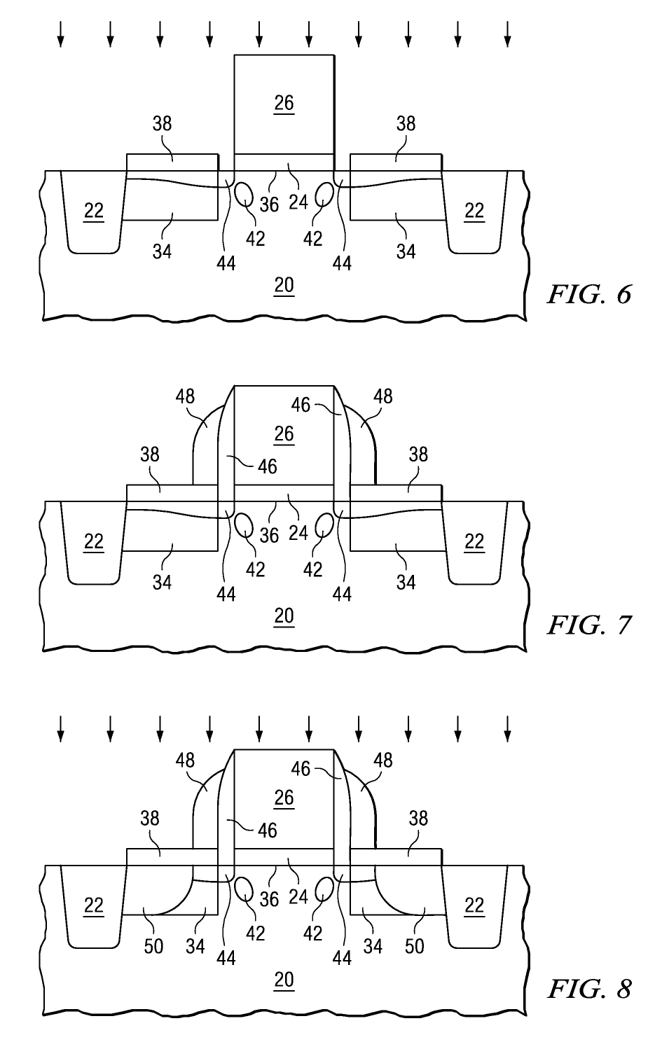

In FIG. 6, dummy slim spacers 28 are removed, and an optional pre-amorphized implantation (PAI) is performed to reduce the dopant channeling effect and to enhance dopant activation. In the preferred embodiment, silicon, germanium, and/or carbon are implanted. In other embodiments, inert gases, such as neon, argon, krypton, xenon, and radon, are used. The PAI prevents subsequently doped impurities from channeling through spaces between the crystal lattice structure and reaching depths greater than desirable. As a result of the PAI, at least top portions of the exposed silicon layers 38 and/or SiC regions 34 are turned to an amorphous state.

FIG. 6 also illustrates the formation of pocket/halo regions 42, preferably by implanting (as symbolized by arrows) p-type impurities, such as boron and/or indium. The implantation may be tilted. Pocket/halo regions 42 are preferably located around the side borders and the junctions of lightly doped source/drain (LDD) regions and deep source/drain regions to neutralize lateral diffusion of the n-type impurities.

Lightly doped drain/source (LDD) regions 44 are also formed, preferably by implanting an n-type impurity, such as phosphorous and/or arsenic. Preferably, the depth of the LDD implantation is greater than the depth of silicon layers 38 to ensure that all silicon layers 38 are implanted. This will prevent the adverse resistance increase if the bottom portions of silicon layers 38 are not silicided in subsequent silicidation process. The details for forming pocket/halo regions 42 and LDD regions 44 are known in the art, thus are not repeated herein.

FIG. 7 illustrates the formation of slim spacers 46 and dummy spacers 48. Slim spacers 46 may have a substantially the same thickness as dummy slim spacers 28 (refer to FIG. 2), although the thickness of spacers 46 may be greater or smaller than that of dummy slim spacers 28. Accordingly, slim spacers 46 have a thickness of less than about 150 Å, and more preferably between about 20 Å and about 100 Å. Dummy spacers 48 may be deposited using similar methods as forming slim spacers 46. The material of dummy spacers 48 is preferably different from the material of slim spacers 46, so that in the subsequent removal of dummy spacers 48, slim spacers 46 are substantially intact. Preferably, dummy spacers 48 have a thickness of between about 100 Å and about 300 Å. In an exemplary embodiment, dummy spacers 48 are thicker than slim spacers 46. Dummy spacers 48 will have at least a portion, likely all, on silicon layers 38 or the raised SiC regions 34.

FIG. 8 illustrates the formation of deep source/drain regions 50, for example, preformed by implanting an n-type impurity. Dummy spacers 48 are then removed. After the removal of dummy spacers 48, silicide regions 52 are formed, as is shown in FIG. 9. As is well known in the art, silicide regions 52 are preferably formed by blanket depositing a thin layer of metal, such as nickel, cobalt, and the like. The substrate is then heated, causing silicon to react with the metal where contacted. After the reaction, a layer of metal silicide is formed between silicon and metal. The un-reacted metal is selectively removed through the use of an etchant that attacks metal but does not attack silicide regions 52.

Silicide regions 52 each include two portions, portion 52₁, directly on the respective LDD region 44, and portion 52₂ on the respective deep source/drain region 50. Due to high concentrations in deep source/drain regions 50, the contacts between portions 52₂ and the underlying deep source/drain regions 50 are Ohmic contacts. The contacts between portions 52₁, and the underlying LDD regions 44 (or the remaining portion of silicon layers 38) are likely to be Schottky contacts due to the low impurity concentration in LDD region 44, or Ohmic contacts. Throughout the description, portions 52₁, of the respective silicide regions 52 are referred to as metallized source/drain regions.

In the preferred embodiment, silicon layers 38 or the portions of the SiC regions 34 higher than interface 36 are fully consumed by the silicidation process. As a result, silicide regions 52 each have a top surface higher than interface 36, and a bottom surface lower than interface 36. In other embodiments, the silicidation process only consumes the top portions of silicon layers 38, and thus lower portions of silicon layers 38 remain after the silicidation process, as is shown in FIG. 9B. Accordingly, the bottom surfaces of silicide regions 52 are higher than interface 36. In above-discussed embodiments, silicide regions 52 are still elevated since they are higher than if formed directly on substrate 20.

FIGS. 9C and 9D illustrate alternative embodiments of the present invention, wherein the NMOS devices are formed on different types of substrates. In FIG. 9C, substrate 20 includes silicon substrate 20₁, partially relaxed silicon germanium (SiGe) layer 20₂, fully relaxed SiGe layer 20₃, and bi-axially strained silicon layer 20₄. Due to the lattice mismatch between silicon layer 20₄ and the underlying layers, strained silicon layer 20₄ has a tensile stress. The tensile stress is further strengthened by the formation of SiC regions 34. FIG. 9D illustrates an NMOS device formed on a well-known SSOI structure, which includes semiconductor substrate 20₅, buried oxide layer 20₆, and strained silicon layer 20₇. Preferably, the stress in silicon layer 20₇ is greater than about 200 MPa, although greater stress is more preferable.

The embodiments of the present invention have several advantageous features. First, due to the formation of slim spacers 46 and dummy spacers, silicide regions 52 are formed close to the channel regions. This significantly reduces the source/drain resistances R_{SD}. Accordingly, the drive current of the resulting NMOS device is improved. The embodiments of the present invention are particularly useful for 65 nm technologies and below, in which the source/drain resistances R_{SD} become a dominant part for preventing the improvement of drive currents. Second, by forming SiC regions, the carrier mobility in the channel region of the NMOS device is improved, resulting in an improved drive current. Third, by raising silicide regions 52 either through forming epitaxial silicon layers or forming SiC regions with top surfaces higher than interface 36, the leakage currents are reduced.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor structure comprising:
a semiconductor substrate;
a gate dielectric over the semiconductor substrate;
a gate electrode over the gate dielectric;
a silicon carbon (SiC) region adjacent the gate dielectric and having at least a portion in the semiconductor substrate;
a deep source/drain region; and
a silicide region over the semiconductor substrate, wherein a horizontal spacing between an inner edge of the silicide region and a respective edge of the gate electrode is less than about 150 Å.

2. The semiconductor structure of claim 1 further comprising a lightly doped source/drain (LDD) region having an inner edge closer to the gate electrode than the inner edge of the silicide region, wherein the silicide region comprises a first portion directly on the LDD region, and a second portion directly on the deep source/drain region.

3. The semiconductor structure of claim 2, wherein the silicide region has a Schottky contact with the LDD region.

4. The semiconductor structure of claim 1 further comprising a silicon layer between the silicide region and the SiC region, wherein the silicon layer has a substantially smaller carbon concentration than in the SiC region.

5. The semiconductor structure of claim 1, wherein the silicide region is spaced apart from the gate dielectric and the gate electrode by a slim spacer having a thickness of less than about 150 Å.

6. The semiconductor structure of claim 1, wherein the SiC region has a carbon atomic percentage of between about one percent and about four percent.

7. The semiconductor structure of claim 1, wherein the silicide region has a bottom surface higher than a bottom surface of the gate dielectric.

8. The semiconductor structure of claim 1, wherein the silicide region has a bottom surface lower than a bottom surface of the gate dielectric.

9. A semiconductor structure comprising:
a semiconductor substrate;
a gate dielectric layer over the semiconductor substrate;
a gate electrode over the gate dielectric layer;
a slim spacer on a sidewall of the gate electrode;
a SiC stressor in the semiconductor substrate and adjacent the gate electrode; and
a silicide region having an inner edge substantially aligned to an outer edge of the slim spacer, wherein the silicide region has a bottom surface substantially higher than a bottom surface of the gate dielectric layer, and wherein a horizontal spacing between an inner edge of the silicide region and a respective edge of the gate electrode is less than about 150 Å.

10. The semiconductor structure of claim 9, wherein the silicide region comprises silicon and carbon.

11. The semiconductor structure of claim 9, wherein the silicide region comprises silicon and is substantially free from carbon.

12. The semiconductor structure of claim 9 further comprising an epitaxy silicon layer between the SiC stressor and the silicide region.

13. The semiconductor structure of claim 9 further comprising a deep source drain region, wherein the deep source/drain region is space apart further from the gate electrode than the inner edge of the silicide region.

14. The semiconductor structure of claim 9, wherein the slim spacer has a thickness of less than about 150 Å.

15. The semiconductor structure of claim 9 further comprising a lightly doped source/drain (LDD) region, wherein the LDD region has an inner edge substantially aligned with an edge of the gate electrode.

16. A semiconductor structure comprising:
a semiconductor substrate comprising a buried oxide layer;
a gate dielectric over the semiconductor substrate;
a gate electrode over the gate dielectric;
a silicon carbon (SiC) region adjacent the gate dielectric and having at least a portion in the semiconductor substrate;
a deep source/drain region comprising at least a portion of the SiC region, wherein the deep source/drain region and the SiC region are over the buried oxide layer; and
a silicide region over the deep source/drain region, wherein a horizontal spacing between an inner edge of the silicide region and a respective edge of the gate electrode is less than about 150 Å.

17. The semiconductor structure of claim 16, wherein a semiconductor region directly underlying the gate dielectric and over the buried oxide layer has a stress of greater than about 200 MPa.

18. The semiconductor structure of claim 16, wherein the silicide region comprises silicon and carbon.

19. The semiconductor structure of claim 16, wherein the silicide region comprises silicon and is substantially free from carbon.

20. The semiconductor structure of claim 16 further comprising an epitaxy silicon layer between the SiC stressor and the silicide region.
